(19) United States
(12) Patent Application Publication
(10) Pub. No.: US 2014/0151108 A1
(43) Pub. Date: Jun. 5, 2014

(54) BASE SUBSTRATE, MOUNTING STRUCTURE, MODULE, ELECTRONIC APPARATUS, AND MOVING OBJECT

(71) Applicant: Seiko Epson Corporation, Tokyo (JP)

(72) Inventors: Masaru Mikami, Minowa-machi (JP); Takuo Kuwahara, Tatsuno-machi (JP)

(73) Assignee: Seiko Epson Corporation, Tokyo (JP)

(21) Appl. No.: 14/095,288

(22) Filed: Dec. 3, 2013

(30) Foreign Application Priority Data
Dec. 4, 2012 (JP) 2012-265018

(51) Int. Cl. H05K 1/11

(52) U.S. Cl. CPC H05K 1/111
USPC 174/267

(57) ABSTRACT

An insulating container as a base substrate includes a loading portion disposed on the other surface side, and mounting electrodes (mounting terminals) which are provided on a bottom surface having a front and rear relationship with the other surface and are connected to lands (external terminals) disposed on a printed circuit board using solder, a first end of each of the mounting electrodes on a center portion side of the bottom surface is disposed on a center portion side of the bottom surface with respect to a second end of each of the lands positioned on a center portion side of the bottom surface, and a third end on a side opposite to the first end in a plan view is disposed on a center portion side of the bottom surface with respect to a fourth end on a side opposite to the second end in a plan view.

### BACKGROUND

1. Technical Field

The present invention relates to a base substrate, a mounting structure using the base substrate, a module, an electronic apparatus, and a moving object.

2. Related Art

There is known, for example, a surface-mounted electronic device having a configuration of loading various circuit components or the like on a wiring pattern which is formed on a surface of an insulating substrate including a mounting electrode (mounting terminal) on a bottom portion (rear surface). As such a surface-mounted electronic device, for example, a quartz crystal vibrator or a quartz crystal oscillator can be used, and the surface-mounted electronic device has a configuration of loading a piezoelectric vibrating element on the inside of a recess of the surface of an insulating container (insulating substrate) such as ceramics including a mounting electrode on a bottom portion and hermetically sealing the recess with a cover.

In the insulating container of the electronic device which is formed of ceramics or the like, in order to secure conductivity of the mounting electrode which is provided on a container bottom surface and the inside of the container, a castellation having an arc-like shape of a side wall in a plan view is formed on a corner portion of the container bottom surface, and a conductive film which is electrically connected with the mounting electrode is formed on the side wall. The arc-like castellation is effective for preventing solder cracks which occur due to a difference in a coefficient of thermal expansion between a configuration material of the container and a motherboard circuit board (glass epoxy or the like) including a land for solder connection of the mounting electrode on the container bottom surface. That is, since the container formed of a low thermal expansion material such as ceramics is, in general, solder-connected on the land of the motherboard circuit board formed of glass epoxy or the like, if a thermal load is applied thereto after a while, maximum strain occurs on a corner portion of the solder joint portion which is in a position separated farthest from a center portion of the rectangular container bottom surface, and accordingly cracks easily occur on the solder.

In order to prevent occurrence of cracks on the solder-joint portion on the corner portion, there has been proposed a configuration of providing a castellation which has a predetermined length from the corner portion of the base substrate (container) towards both sides, and on a surface of which an electrode is formed, shortening a distance between the corner portion and the center portion of the container bottom surface, and increasing a solder fillet amount to increase a joining strength with the land (connection electrode) of the motherboard circuit board (printed circuit board) (for example, see JP-A-2006-196703). In this configuration, the land and the mounting electrode are formed and disposed so that the mounting electrode which is provided on the container bottom surface is accommodated inside the outer rim of the land of the motherboard circuit board (printed circuit board).

However, in the configuration of the related art described above, a first outer rim of a solder fillet which is formed in a connection portion of an end portion of the mounting electrode (mounting terminal) on the center portion side of the insulating container and the land (external terminal), and a second outer rim of a solder fillet which is formed in the connection portion of an end portion of the mounting electrode (mounting terminal) on a side in which the castellation is provided and the land (external terminal), are in a shape of a trailing skirt, in a plan view, so as to be gradually separated from each other from the mounting electrode towards the land. If the solder fillet having a trailing skirt shape is formed so that the first outer rim and the second outer rim are separated from each other as described above, when a thermal load is applied to the soldered insulating container and the motherboard circuit board (printed circuit board), stress caused by thermal strain which occurs due to a difference in a coefficient of expansion between the insulating container and the printed circuit board is concentrated in the solder fillet, and there is a concern of occurrence of cracks on the solder fillet.

### SUMMARY

An advantage of some aspects of the invention is to solve at least a part of the problems described above, and the invention can be implemented as the following forms or application examples.

### Application Example 1

This application example is directed to a base substrate including: mounting terminals which are connected to electrode pads provided on a mounting substrate using a joining material, in which each of the mounting terminals includes a first end which is disposed on the outside of a region of the electrode pad, in a plan view, and a second end which is overlapped with the inside of the region of the electrode pad.

According to this application example, since the first end of each of the mounting terminals provided on the substrate is overlapped with the outside of the region of each of the external terminals, in a plan view, the solder fillet in this portion is formed to have a trailing skirt shape from the external terminal towards the surface of the mounting terminal.

In addition, since the second end of each of the mounting terminals provided on the substrate is overlapped with the inside of the region of each of the external terminals, in a plan view, the solder fillet in this portion is formed to have a trailing skirt shape from the second end of the mounting terminal towards the external terminal. If the solder fillets are configured with such a configuration, since a joint portion of the solder fillet formed on the first end side and the surface of the mounting terminal becomes thin, bending strength thereof is weakened. Accordingly, when thermal load is applied to the soldered mounting terminals and the external terminals, the solder fillet formed on the first end side is easily deformed, that is, thermal strain stress is released, and therefore it is possible to prevent concentration of the thermal strain stress. Thus, it is possible to suppress cracks on the solder fillet generated due to concentration of the thermal strain stress.

### Application Example 2

This application example is directed to a mounting structure including: a first substrate on which mounting terminals are provided; and a second substrate on which external terminals to which the mounting terminals are attached using a joining material are provided, in which a first end of each of the mounting terminals is disposed in outside of a region of the external terminal, in a plan view, a second end of each of the mounting terminals is overlapped with the inside of the region of the external terminal, in a plan view, a first fillet is provided from the first end to each of the external terminals, and a second fillet is provided from the second end to each of the external terminals.

According to this application example, since the first end of each of the mounting terminals provided on the first substrate is overlapped with the outside of the region of each of the external terminals provided on the second substrate, in a plan view, the first solder fillet in this portion is formed to have a trailing skirt shape from the external terminal towards the surface of the mounting terminal.

In addition, since the second end of each of the mounting terminals provided on the first substrate is overlapped with the inside of the region of each of the external terminals provided on the second substrate, in a plan view, a second solder fillet in this portion is formed to have a trailing skirt shape from the second end of the mounting terminal towards the external terminal. If the solder fillets are configured with such a configuration, since a joint portion of the first solder fillet formed on the first end side and the surface of the mounting terminal becomes thin, bending strength thereof is weakened.

Accordingly, when thermal load is applied to the soldered mounting terminals and the external terminals, the first solder fillet formed on the first end side is easily deformed, that is, thermal strain stress is released, and therefore it is possible to prevent concentration of the thermal strain stress. Thus, it is possible to suppress cracks on the solder fillet generated due to concentration of the thermal strain stress.

### Application Example 3

This application example is directed to the mounting structure according to the application example described above, wherein the first substrate includes the pair of mounting terminals, the second substrate includes the pair of electrode pads, the end on a side where the pair of mounting terminals oppose each other is set to be the first end, the end on a side opposite to the side where the pair of mounting terminals oppose each other is set to be the second end, the first fillet is provided from the first end to each of the electrode pads, and the second fillet is provided from the second end to each of the electrode pads.

According to this application example, since the first end of each of the mounting terminals on a side where the pair of mounting terminals oppose each other is overlapped with the inside of the region between the pair of external terminals with respect to the third end on a side where the external terminals oppose each other, in a plan view, the first solder fillet in this portion is formed to have a trailing skirt shape from the third end side of the external terminal towards the surface of the mounting terminal.

In addition, since the second end of each of the mounting terminals on a side opposite to the first end in a plan view is overlapped with the inside of the region between the third end and the fourth end of the external terminals, in a plan view, the second solder fillet in this portion is formed to have a trailing skirt shape from the second end side of the mounting terminal towards the external terminal. If the solder fillets are configured with such a configuration, since a joint portion of the first solder fillet on a side where the pair of mounting terminals oppose each other and the surface of the mounting terminal becomes thin, bending strength thereof is weakened. Accordingly, when thermal load is applied to the soldered mounting terminals and the external terminals of the second substrate (motherboard circuit board), the first solder fillet is easily deformed, that is, thermal strain stress is released, and therefore it is possible to prevent concentration of the thermal strain stress. Thus, it is possible to suppress cracks on the solder fillet generated due to concentration of the thermal strain stress.

### Application Example 4

This application example is directed to the mounting structure according to the application example described above, wherein the first substrate includes an end portion which extends in a direction intersecting with the first end of each of the mounting terminals, the end portion is overlapped with the inside of each of the electrode pads, in a plan view, and a third fillet is provided from the end portion to each of the electrode pads.

According to this application example, it is also possible to provide the third solder fillet formed to have a trailing skirt shape towards the external terminals, on the end portion intersecting with the first end. Accordingly, in addition to the effect described above, since the amount of solder fillet and the solder amount as the entire solder increase, it is possible to improve solder strength and it is possible to improve the occurrence preventing effect of cracks on the solder fillet.

### Application Example 5

This application example is directed to a module including the mounting structure according to any one of the application examples described above.

According to this application example, since the mounting structure described above is included, it is possible to provide a module having high reliability so as to suppress malfunction such as occurrence of solder cracks due to thermal load on the solder fillets formed when the base substrate is soldered on the motherboard circuit board (printed circuit board).

### Application Example 6

This application example is directed to an electronic apparatus including the mounting structure according to any one of the application examples described above.

According to this application example, since the mounting structure described above is included, it is possible to provide an electronic apparatus having high reliability so as to suppress malfunction such as occurrence of solder cracks due to thermal load on the solder fillets formed when the base substrate is soldered on the motherboard circuit board (printed circuit board).

### Application Example 7

This application example is directed to a moving object including the mounting structure according to any one example of the Application Examples described above.

According to this application example, since the mounting structure described above is included, it is possible to provide an oscillator having high reliability so as to suppress malfunction such as occurrence of solder cracks due to thermal load on the solder fillets formed when the base substrate is soldered on the motherboard circuit board (printed circuit board).

### BRIEF DESCRIPTION OF THE DRAWINGS

The invention will be described with reference to the accompanying drawings, wherein like numbers reference like elements.

FIGS. 1A to 1C show a schematic configuration and a soldering state of a surface-mounted quartz crystal vibrator according to a first embodiment using a base substrate according to the invention, wherein FIG. 1A is a plan view, FIG. 1B is a front cross-sectional view, and FIG. 1C is a bottom view when FIG. 1A is seen from a rear surface side.

FIG. 2A is a front cross-sectional view showing solder fillets which are formed between a mounted-surface quartz crystal vibrator and lands of a printed circuit board according to the first embodiment, and FIG. 2B is a front cross-sectional view showing solder fillets having a configuration of the related art which are shown as Comparative Example.

FIGS. 3A to 3C show a schematic configuration and a soldering state of a surface-mounted quartz crystal vibrator according to a second embodiment using a base substrate according to the invention, wherein FIG. 3A is a plan view, FIG. 3B is a front cross-sectional view, and FIG. 3C is a bottom view when FIG. 3A is seen from a rear surface side.

FIGS. 4A and 4B are views showing a state of solder fillets of a surface-mounted quartz crystal vibrator according to the second embodiment, wherein FIG. 4A is a perspective view and FIG. 4B is a cross-sectional view taken along line P-P of FIG. 4A.

FIG. 5A is a simulation diagram showing thermal strain stress distribution of solder fillets of a surface-mounted quartz crystal vibrator according to the second embodiment, and FIG. 5B is a simulation diagram showing thermal strain stress distribution of solder fillets of Comparative Example.

FIGS. 6A and 6B are front cross-sectional views showing an oscillator using a base substrate according to the invention.

FIGS. 7A and 7B are front cross-sectional views showing an electronic device using a base substrate according to the invention.

FIG. 8 is a perspective view showing a configuration of a mobile personal computer as an example of an electronic apparatus.

FIG. 9 is a perspective view showing a configuration of a mobile phone as an example of an electronic apparatus.

FIG. 10 is a perspective view showing a configuration of a digital still camera as an example of an electronic apparatus.

FIG. 11 is a perspective view showing a configuration of an automobile as an example of a moving object.

### DESCRIPTION OF EXEMPLARY EMBODIMENTS

Hereinafter, the invention will be specifically described based on embodiments shown in the accompanied drawings. In the following embodiments, a surface-mounted quartz crystal vibrator will be described as an example of a surface-mounted piezoelectric vibrator using abase substrate according to the invention.

### First Embodiment

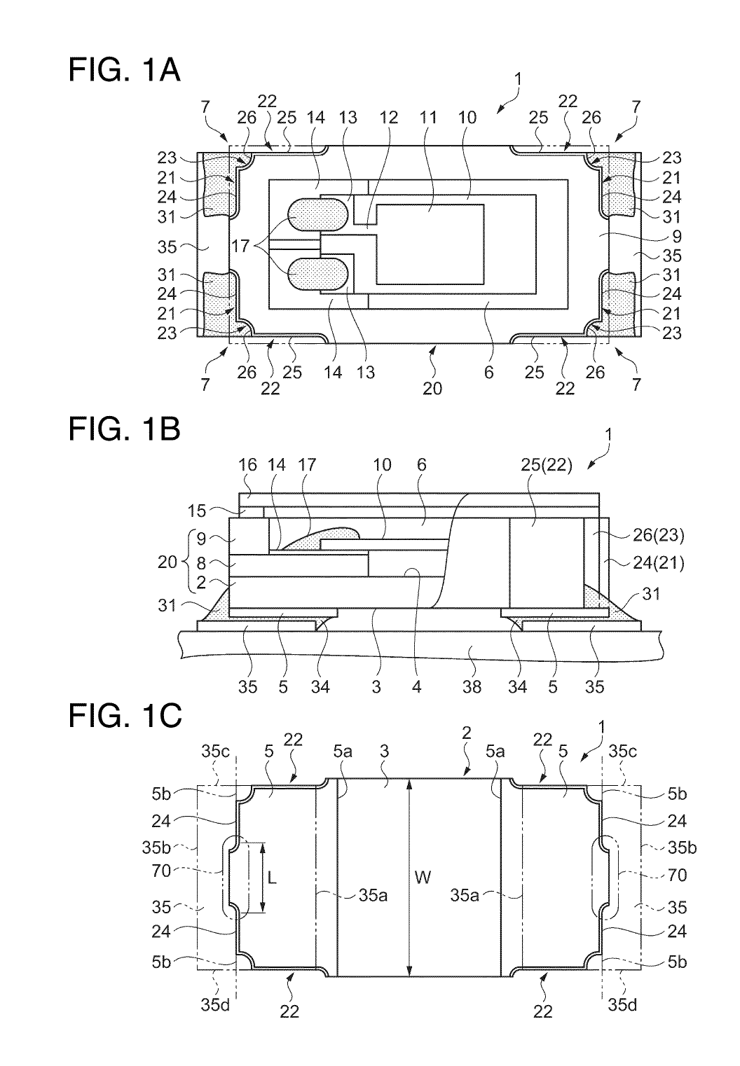

A surface-mounted quartz crystal vibrator according to a first embodiment using a base substrate according to the invention, and a mounting structure using the surface-mounted quartz crystal vibrator will be described with reference to the drawings. FIGS. 1A to 1C show a schematic configuration and a soldering state of the surface-mounted quartz crystal resonator according to the first embodiment of the invention, wherein FIG. 1A is a plan view, FIG. 1B is a partial longitudinal front cross-sectional view, and FIG. 1C is a bottom view when FIG. 1A is seen from a rear surface side. In the plan view of FIG. 1A, a seal ring and a cover are omitted for convenience of description. The surface-mounted quartz crystal resonator is an example of the resonators.

A quartz crystal resonator 1 has a configuration of accommodating a quartz crystal vibrating element 10 in a loading portion 6 which is a recess of an insulating container (package) 20 as a base substrate (first substrate) obtained by laminating a bottom plate 2, a loading plate 8, and a wall plate 9 which are formed of a sheet-like insulating material such as a ceramic sheet, and sealing the loading portion 6 with a metallic cover 16 by seam welding.

Herein, the quartz crystal resonator 1 is not limited thereto, and may have a structure of accommodating the quartz crystal vibrating element 10 in the loading portion 6 which is a recess of the insulating container (package) 20 having a recessed shape formed of laminated ceramics, joining the cover 16 formed of ceramics by performing glass sealing of an opened end surface of the insulating container 20, and hermetically sealing the quartz crystal vibrating element 10.

In the insulating container (package) 20 as the base substrate (first substrate), the bottom plate 2, the loading plate 8 as a loading plate of the quartz crystal vibrating element 10, and the wall plate 9 as an outer wall are laminated in this order. The insulating container 20 is a circuit wiring board having an approximately rectangular container shape in a plan view, and mounting electrodes (first terminals) 5 as mounting terminals which are provided to contain two corners of a bottom surface (one surface) 3 of the approximately rectangular bottom plate 2 are provided. The mounting electrodes (first terminals) 5 are, for example, conductive metallic layers having a configuration of performing gold (Au) plating on a burnt nickel (Ni) metallization layer as underlying metal. In the insulating container 20, the loading portion 6 which is a recess surrounded by an opening portion of the loading plate 8 and the wall plate 9 is provided on the other surface 4 side which has a front and rear relationship with the bottom surface 3 of the bottom plate 2. The other surface 4 is a surface on a side of the insulating container 20 which is connected to the cover 16, and indicates one surface of the bottom plate 2 in the drawing for convenience. Two inner pads 14 which are electrically connected to the quartz crystal vibrating element 10 are provided on an exposed surface of the loading plate 8 which is exposed in the loading portion 6. Each inner pad 14 is electrically connected to the corresponding mounting electrode 5. However, the description thereof is omitted in the drawing.

In addition, in the approximately rectangular four corner portions 7 of the insulating container 20, first cut-out portions (castellation) 23 are provided on a side surface of the corner portions 7 of the insulating container 20, from the corner portion 7 of the bottom plate 2 on the bottom surface 3 side towards the corner portions 7 on the other surface 4 side. That is, the first cut-out portions (castellation) 23 are provided on the side surfaces from the bottom surface 3 of the bottom plate 2 to an upper surface of the wall plate 9 (surface on which a seal ring 15 for connecting the cover 16 is formed). First cut-out portions 23 are formed to include curved lines and to be recessed towards the center side, when the insulating container 20 is seen in a plan view. In this example, the first cut-out portions are formed in a shape of a so-called arc-like recess.

In addition, a second cut-out portion 21 and a third cut-out portion 22 which are provided to extend from the first cut-out portion 23 are provided on both side surfaces of the insulating container 20 with the first cut-out portion 23 interposed therebetween. The second cut-out portion 21 and the third cut-out portion 22 are provided towards the other surface 4 side from the corner portion 7 of the bottom plate 2 on the bottom surface 3 side, in the same manner as the first cut-out portion 23. That is, the second cut-out portion 21 and the third cut-out portion 22 are provided on the side surfaces from the bottom surface 3 of the bottom plate 2 to the upper surface of the wall plate 9 (surface on which the seal ring 15 for connecting the cover 16 is formed), in the same manner as the first cut-out portion 23. When the insulating container 20 is seen in a plan view, the second cut-out portion 21 and the third cut-out portion 22 are recessed cut-outs having a predetermined length from the outer periphery of the insulating container 20 towards the inside thereof, and each one end thereof is connected to the first cut-out portion 23. Each of the other ends which are extended from the one end connected to the first cut-out portion 23 with a predetermined length is provided to have an arc shape.

Second terminals 26, 24, and 25, which are metallic layers, are provided on the surfaces of the first cut-out portion 23, the second cut-out portion 21, and the third cut-out portion 22, respectively. That is, the second terminal 26 is formed on the surface of the first cut-out portion 23, the second terminal 24 is formed on the surface of the second cut-out portion 21, and the second terminal 25 is formed on the surface of the third cut-out portion 22. The second terminals 26, 24, and 25 are preferably formed with metal having excellent solder wettability for securing a soldering property of the quartz crystal resonator 1 which will be described later, and a configuration of performing gold (Au) plating on a burnt nickel (Ni) metallization layer as underlying metal is used, for example. The second terminals 26, 24, and 25 may have conductivity and may have a configuration to be used as electrode layers by being connected to the mounting electrode 5 as the first terminal. In addition, the configuration of the second terminals 26, 24, and 25 described herein is one example, and another metal may be used as long as it has a function as electrode layers or soldering layers.

A protrusion 70 is provided between the second cut-out portion 21 and the third cut-out portion 22. The mounting electrode (first terminal) 5 is also provided on the bottom surface 3 on which the protrusion 70 is formed. Accordingly, while an area of an adhesion region is decreased in a plan view, as the first cut-out portion 23 is provided on the corner portion 7, the area of the adhesion region can be increased (so-called earned) by an area of the mounting electrode 5 of a portion in which the protrusion 70 is provided, and strength of the solder joint is maintained not to be decreased, or is strengthened.

In addition, a width L of the protrusion 70 is preferably equal to or less than 50% (L/W≦50(%)) with respect to a width W of a package. Accordingly, in a manufacturing step of the base substrate, a number of burrs which occur when breaking from the motherboard to individual pieces can be decreased.

In the description, the configuration of providing the second cut-out portion 21 and the third cut-out portion 22 which extend from the first cut-out portion 23 are provided on both side surfaces of the insulating container 20 with the first cut-out portion 23 interposed therebetween has been described. However, the invention is not limited thereto. At least one cut-out portion of the second cut-out portion 21 and the third cut-out portion 22 which extend from the first cut-out portion 23 may be provided on the side surface of the insulating container 20.

In the quartz crystal vibrating element 10, an excitation electrode 11 is formed on front and rear main surfaces, and two connection electrodes 13 are provided through a wiring electrode 12 which is extended from the excitation electrode 11. The quartz crystal vibrating element 10 is electrically connected and fixed to the inner pad 14 which is provided in the loading portion 6 of the loading plate 8 configuring the insulating container 20, by using a conductive adhesive 17 or the like.

The loading portion 6 in which the quartz crystal vibrating element 10 is accommodated, is sealed by seam welding of the cover 16 and the insulating container 20 (wall plate 9) through the seal ring 15 which is provided on the upper surface of the wall plate 9 configuring the insulating container 20. The cover 16 is also called a lid, and can be formed, for example, using metal such as alloy 42 (alloy containing 42% of nickel in iron) or kovar (alloy of iron, nickel, and cobalt), ceramics, or glass. In a case where the cover 16 is formed by metal, for example, the seal ring 15 is formed by die cutting of the kovar alloy or the like in a rectangular ring shape. Since the loading portion 6 which is a recessed space formed by the insulating container 20 and the cover 16 is a space for operating the quartz crystal vibrating element 10, it is preferable to be hermetically sealed and enclosed to be a reduced-pressure space or to have an inert gas atmosphere.

The quartz crystal resonator 1 of the above configuration is mounted by soldering on a circuit board or another printed circuit board 38 as a substrate (second substrate), or the like. In the drawing, a state is shown in which the quartz crystal resonator 1 is loaded on the printed circuit board (second substrate) 38 as a substrate in which lands 35 as electrodes are provided, and the lands 35 of the printed circuit board 38 and the mounting electrodes 5 as the mounting terminals of the quartz crystal resonator 1 are connected and fixed to each other by soldering. Hereinafter, a positional relationship between the lands (external terminals) 35 of the printed circuit board 38 and the mounting electrodes 5 of the quartz crystal resonator 1 will be described.

In the quartz crystal resonator 1 of this example, the pair of mounting electrodes 5 are provided on the bottom surface 3 of the insulating container 20 on each end side in which the second cut-out portion 21 is provided. The lands 35 as the external terminals which are disposed to be a pair so as to face each of the pair of mounting electrodes 5 are provided on the printed circuit board 38. The pair of mounting electrodes 5 and the facing pair of lands 35 are electrically connected and fixed to each other by soldering.

Each of the pair of mounting electrodes 5 includes a first end 5a on the center portion side of the bottom surface 3. That is to say, each first end 5a of the pair of mounting electrodes 5 is a facing end of the pair of mounting electrodes 5. In addition, each of the pair of mounting electrodes 5 includes a third end 5b in a position overlapped with the end of the insulating container 20 on a side where the second cut-out portion 21 is provided, as an end on a side opposite to the first end 5a. The pair of mounting electrodes 5 are provided so as to cover the bottom surface 3 between the first end 5a and the third end 5b.

Each of the lands 35 which are provided on the printed circuit board 38 as the substrate (second substrate) includes a second end 35a on a side farther than the first end 5a of the mounting electrode 5 from the center portion of the insulating container 20, that is, a side close to the second cut-out portion 21 of the insulating container 20. That is, the second ends 35a of the lands 35 are ends on sides of the pair of lands 35 which face each other. In addition, the first end 5a of the mounting electrode 5 is disposed so as to be overlapped with the outside of the region of the land 35, in a plan view. The land 35 is provided between the second end 35a and the fourth end 35b which is positioned on the outer side (farther position when seen from the center portion of the insulating container 20) of the insulating container 20 with respect to the third end 5b of the mounting electrode 5. That is, the second end 35a and the fourth end 35b on a side opposite to the second end 35a in a plan view are provided on the land 35. That is to say, the second end 5b of the mounting electrode 5 is overlapped with the inner side of the region of the land 35, in a plan view. In addition, sixth ends 35c and 35d which are ends intersecting with the second end 35a and the fourth end 35b are provided on the land 35. The sixth ends 35c and 35d are provided on positions substantially overlapping with the insulating container 20 in a direction where the third cut-out portion 22 is provided, in a plan view. As described above, the land 35 is an electrode surrounded by the second end 35a, the fourth end 35b, and the sixth ends 35c and 35d.

Each of the pair of mounting electrodes 5 which are provided on the bottom surface 3 of the insulating container 20 is disposed, so that the first end 5a is positioned on the center portion side of the bottom surface 3 with respect to the second end 35a of the land 35, and the third end 5b is positioned on the center portion side of the bottom surface 3 with respect to the fourth end 35b of the land 35, and the mounting electrodes 5 are soldered to the land 35. In addition, fifth ends which are ends in a direction intersecting with the first end 5a and the third end 5b of each of the pair of mounting electrodes 5, are disposed in a position substantially overlapping with the sixth ends 35c and 35d of the land 35 in a plan view. That is, the fifth ends of the mounting electrode 5 are provided substantially along the side surface of the insulating container 20 on a side where the third cut-out portion 22 is provided.

As described above, if the quartz crystal resonator 1 is soldered on the lands 35 of the printed circuit board 38, solder fillets are formed between the insulating container 20 and the lands 35. The solder fillets will be described. The solder fillets are roughly divided into two solder fillets (first solder fillets 34 and second solder fillets 31), and formation states of the two solder fillets affect strength and long-time reliability of the soldering.

Each of the second solder fillets 31 is solder having a trailing skirt shape in a curved line shape, from the second terminals 26 and 24 provided on the first cut-out portion 23 and the second cut-out portion 21 of the insulating container 20, towards the surface of the land 35 which is exposed to the outside of the insulating container 20 in a plan view. Each of the first solder fillets 34 is solder having a trailing skirt shape in a curved line shape, from the side surface of the second end 35a of the land 35, towards the surface of the mounting electrode 5 exposed to the center portion side of the bottom surface 3 of the insulating container 20 in a plan view.

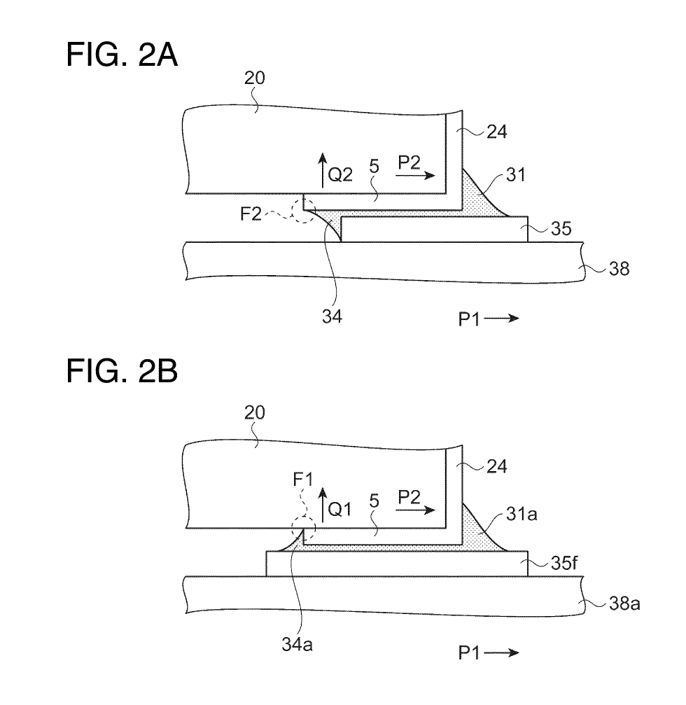

By using such a quartz crystal resonator 1 and a printed circuit board 38 on which the solder fillets (first solder fillets 34 and second solder fillets 31) can be formed as described above, it is possible to suppress cracks on the solder fillets generated due to concentration of thermal strain stress. This will be described with reference to FIGS. 2A and 2B. FIG. 2A is a front cross-sectional view showing the first solder fillets 34 and the second solder fillets 31, which are formed between the surface-mounted quartz crystal resonator 1 and the lands 35 of the printed circuit board 38 according to the first embodiment, and FIG. 2B is a front cross-sectional view showing solder fillets having a configuration of the related art which are shown as Comparative Example.

First, the configuration of the related art shown in FIG. 2B will be described. In the configuration of the related art shown in FIG. 2B, the mounting electrode 5 of the insulating container 20 is soldered on a land 35f of a printed circuit board 38a. An eleventh solder fillet 31a having a trailing skirt shape in a curved line shape from the second terminal 24 towards the surface of the land 35f exposed to the outside of the insulating container 20 in a plan view, is formed on the outside of the insulating container 20. In addition, a twelfth solder fillet 34a having a trailing skirt shape in a curved line shape from the side surface (end periphery) of the mounting electrode 5 on the center portion side, towards the exposed surface of the land 35f in a plan view, is formed on the center portion side of the insulating container 20. As described above, in the cross section shown in FIG. 2B, the eleventh solder fillet 31a and the twelfth solder fillet 34a have a trailing skirt shape towards the same land 35f. That is, when seen in a front cross-sectional direction, the eleventh solder fillet 31a and the twelfth solder fillet 34a are soldered in a trapezoidal shape, with the land 35f interposed therebetween.

Next, an aspect of the first embodiment according to the invention shown in FIG. 2A will be described. In the aspect of the mounting structure of the first embodiment according to the invention shown in FIG. 2A, the mounting electrode 5 of the insulating container 20 is soldered on the land 35 of the printed circuit board 38.

In addition, the invention is not limited to the solder, and the mounting electrode 5 may be joined with the land 35 using a joining material such as low-melting-point metal, eutectic metal, or a conductive adhesive.

The first fillet 34 having a trailing skirt shape in a curved line shape from the side surface (end periphery) of the land 35 on the center side towards the surface of the mounting electrode 5 exposed in a plan view, is formed on the center portion side of the insulating container 20. In addition, the second solder fillet 31 having a trailing skirt shape in a curved line shape from the second terminal 24 towards the surface of the land 35 exposed to the outside of the insulating container 20 in a plan view, is formed on the outside of the insulating container 20. As described above, in the cross section shown in FIG. 2A, the outer periphery of the first solder fillet 34 and the outer periphery of the second solder fillet 31 have a trailing skirt shape in the same direction as each other. That is, the first solder fillet 34 and the second solder fillet 31 with the land 35 interposed therebetween, have a substantially point-symmetric shape with respect to an intermediate point of the first solder fillet 34 and the second solder fillet 31, and are soldered with the solder in a space where the land 35 and the mounting electrode 5 oppose each other.

If a thermal load such as a high temperature or a low temperature is applied with respect to the mounting structure obtained by the soldered insulating container 20 and the printed circuit boards 38 and 38a in the configuration of the related art and the aspect of the first embodiment according to the invention, thermal expansion or thermal contraction occurs in each of the printed circuit boards 38 and 38a and the insulating container 20. For example, in a case where the high temperature is applied, the printed circuit board 38 expands in a direction of an arrow P1 in the drawing, and the insulating container 20 also expands in a direction of an arrow P2 in the drawing, in the same manner. At that time, since the printed circuit board 38 generally having a great coefficient of thermal expansion has a greater amount of change in a position than the insulating container 20, a force by the thermal expansion is applied in directions of arrows Q1 and Q2 in the drawings, and stress caused by thermal strain is concentrated on portions F1 and F2 shown in the drawings.

As described above, in a case where the stress caused by the thermal strain is concentrated on the portions F1 and F2, in the configuration of the related art shown in FIG. 2B, since the outer periphery of the eleventh solder fillet 31a and the outer periphery of the twelfth solder fillet 34a are formed to be inclined so as to gradually become close to each other from the land 35f towards the mounting electrode 5, the twelfth solder fillet 34a is not easily deformed, and the stress in the direction of the arrow Q1 in the drawing is not easily released. That is, the stress cannot be released, and the stress caused by the thermal strain is easily concentrated on a spot of the portion F1. In addition, in a so-called temperature cycle (for example, from +150° C. to −55° C.) in which the high temperature and the low temperature are repeatedly applied, the thermal strain stress due to expansion and contraction is repeatedly applied to the spot of the portion F1, and this is a reason for occurrence of cracks on the solder due to accumulated fatigue of the solder.

Meanwhile, in the aspect of the first embodiment according to the invention shown in FIG. 2A, the outer periphery of the first solder fillet 34 and the outer periphery of the second solder fillet 31 have a trailing skirt shape in the same direction with each other. Accordingly, the solder attached to the spot of the portion F2 is thin and rigidity thereof is weak. With the weakened rigidity of the solder as described above, deflection (deformation) of the first solder fillet 34 easily occurs, and the stress in the direction of the arrow Q2 in the drawing is easily released with this deflection, and accordingly the concentration of the stress caused by the thermal strain does not easily occur. Therefore, even in the so-called temperature cycle (for example, from +150° C. to −55° C.) in which the high temperature and the low temperature are repeatedly applied, the stress caused by the thermal strain is not easily accumulated on the spot of the portion F2, and the accumulated fatigue of the solder is suppressed, and thus it is possible to prevent occurrence of solder cracks.

According to the configuration of the mounting structure in which the quartz crystal resonator 1 is connected by soldering with the printed circuit board 38, using the quartz crystal resonator 1 as the first embodiment using the base substrate according to the invention, the following effects are obtained. According to the configuration, when the thermal load is applied to the mounting electrodes 5 of the soldered insulating container 20 configuring the quartz crystal resonator 1, and the lands 35 as the electrodes of the printed circuit board 38, the first solder fillets 34 of the insulating container 20 on the center portion side of the bottom surface 3 is easily deflected (easily deformed). That is, with the deformation of the first solder fillets 34, the thermal strain stress generated by applying the thermal load is released, and it is possible to prevent the concentration of the thermal strain stress. Accordingly, it is possible to reduce occurrence of the cracks on the first solder fillets and the second solder fillets 31 which occur due to concentration of the stress caused by the thermal strain. Therefore, even when the quartz crystal resonator 1 using the insulating container 20 as the base substrate according to the invention is loaded on a device used in an environment of a high temperature or a low temperature, it is possible to reduce occurrence of malfunction such as connection failure due to solder degradation.

In particular, in a quartz crystal vibrating element which is obtained by joining a cover formed of ceramics by glass sealing of a recessed opened end surface of an insulating container formed of laminated ceramics, since a sealing portion is sealed by glass sealing and the strength of the glass sealing is weaker than the seam welding, there is a concern of destruction of airtightness of the glass sealing portion. However, if the mounting structure of the invention is applied, since it is also possible to reduce stress caused by the thermal strain applied to the glass sealing portion, an advantageous effect of maintaining the airtightness of the glass sealing portion is exhibited.

### Second Embodiment

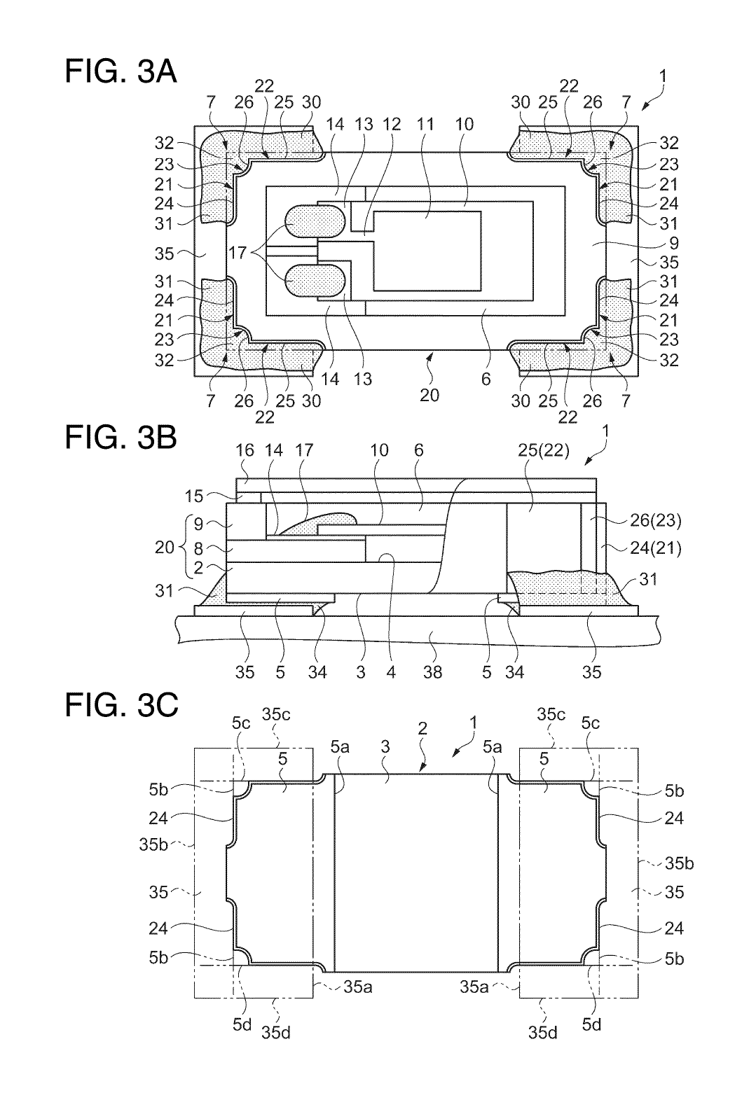

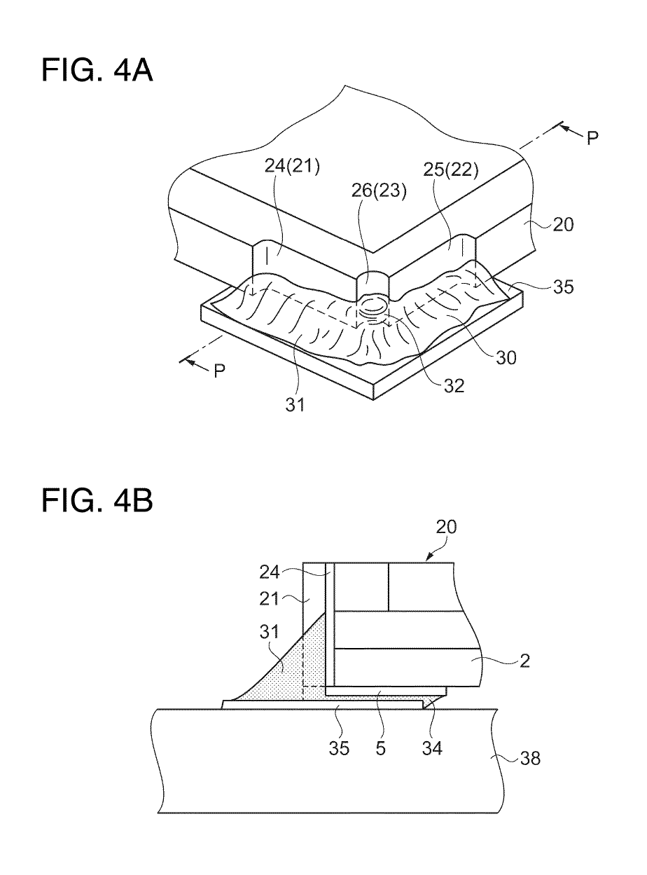

A surface-mounted quartz crystal resonator according to a second embodiment using the base substrate according to the invention, and amounting structure using the surface-mounted quartz crystal resonator will be described with reference to FIGS. 3A to 3C and 4A and 4B. FIGS. 3A to 3C show a schematic configuration and a soldering state of the surface-mounted quartz crystal resonator according to the second embodiment of the invention, wherein FIG. 3A is a plan view, FIG. 3B is a partial longitudinal front cross-sectional view, and FIG. 3C is a bottom view when FIG. 3A is seen from a rear surface side. In the plan view of FIG. 3A, a seal ring and a cover are omitted for convenience of description. FIGS. 4A and 4B are views showing states of the solder fillets of the surface-mounted quartz crystal resonator according to the second embodiment, wherein FIG. 4A is a perspective view and FIG. 4B is a cross-sectional view taken along line P-P of FIG. 4A. In the following description, the description of the same configuration as the first embodiment described above is omitted by denoting the same reference numerals.

To describe differences between the second embodiment and the first embodiment described above, the shape of the lands 35 as the electrodes provided on the printed circuit board 38 is different, and the positional relationship with the mounting electrodes 5 as the mounting terminals provided on the bottom surface 3 of the insulating container 20 of the quartz crystal resonator 1 is changed. Since the configuration of the quartz crystal resonator 1 according to the second embodiment is the same as that of the quartz crystal resonator 1 of the first embodiment described above, the description thereof is omitted by denoting the same reference numerals.

The quartz crystal resonator 1 of the above configuration is mounted by soldering on a circuit board or another printed circuit board 38 as a substrate (second substrate), or the like. In the drawing, the mounting structure is shown in which the quartz crystal resonator 1 is loaded on the printed circuit board 38 as a substrate in which the lands 35 as external terminals are provided, and the lands 35 of the printed circuit board 38 and the mounting electrodes 5 of the quartz crystal resonator 1 are connected and fixed to each other by soldering. Hereinafter, a positional relationship between the lands 35 of the printed circuit board 38 and the mounting electrodes 5 of the quartz crystal resonator 1 will be described.

In the quartz crystal resonator 1 of the second embodiment, the pair of mounting electrodes 5 are provided on the bottom surface 3 of the insulating container 20 on each end side in which the second cut-out portion 21 is provided, in the same manner as the first embodiment. The lands 35 as the electrodes which are disposed to be a pair so as to face each of the pair of mounting electrodes 5 are provided on the printed circuit board 38. The pair of mounting electrodes 5 and the facing pair of lands 35 are electrically connected to each other by soldering.

Each of the pair of mounting electrodes 5 includes a first end 5a on the center portion side of the bottom surface 3. That is to say, the first end 5a of each of the pair of mounting electrodes 5 is a facing end of the pair of mounting electrodes 5. In addition, each of the pair of mounting electrodes 5 includes a third end 5b in a position overlapped with the end of the insulating container 20 on a side where the second cut-out portion 21 is provided, as an end on a side opposite to the first end 5a. The pair of mounting electrodes 5 include the fifth ends 5c and 5d intersecting with the first end 5a. When the bottom surface 3 is seen in a plan view, the fifth ends 5c and 5d are formed to include portions overlapping with the surface of the second terminal 25 provided on the third cut-out portion 22. That is, the fifth ends 5c and 5d are formed along the side surface of the insulating container 20 on a side where the third cut-out portion 22 is provided. As described above, the pair of mounting electrodes 5 are provided so as to cover the bottom surface 3 from the first end 5a to the third end 5b.

Each of the lands 35 which are provided on the printed circuit board 38 includes the second end 35a on a side farther than the first end 5a of the mounting electrode 5 from the center portion of the insulating container 20, that is, a side where the second cut-out portion 21 of the insulating container 20 is provided. The fourth end 35b is positioned on the outer side of the insulating container 20 with respect to the third end 5b of the mounting electrode 5, from the second end 35a. That is, the second end 35a and the fourth end 35b, which is positioned on a side opposite to the second end 35a in a plan view, are provided on the land 35. In addition, the sixth ends 35c and 35d, which are ends intersecting with the second end 35a and the fourth end 35b, are provided on the land 35. The sixth ends 35c and 35d are provided on positions to be an outer side with respect to the side surface of the insulating container 20 in a direction where the third cut-out portion 22 is provided, in a plan view. As described above, the land 35 is an electrode surrounded by the second end 35a, the fourth end 35b, and the sixth ends 35c and 35d.

Each of the pair of mounting electrodes 5 which are provided on the bottom surface 3 of the insulating container 20 is disposed so that the first end 5a is positioned on the center portion side of the bottom surface 3 with respect to the second end 35a of the land 35, and the third end 5b is positioned on the center portion side of the bottom surface 3 with respect to the fourth end 35b of the land 35. In addition, the fifth ends 5c and 5d of the pair of mounting electrodes 5 provided on the insulating container 20 are disposed so as to be positioned on the inner side with respect to the sixth ends 35c and 35d of the lands 35, in a plan view. That is, the sixth ends 35c and 35d of the lands 35 are disposed so as to be positioned on the outer side with respect to fifth ends 5c and 5d of the pair of mounting electrodes 5, in a plan view. As described above, the pair of the mounting electrodes 5 and the lands 35 are disposed and soldered, and accordingly, the insulating container 20 is fixed to the printed circuit board 38.

As described above, if the quartz crystal resonator 1 is soldered on the lands 35 of the printed circuit board 38, the solder fillets are formed between the insulating container 20 and the lands 35. The solder fillets will be described with reference to FIGS. 4A and 4B. The solder fillets are roughly divided into the first solder fillet 34 formed on the center portion side of the insulating container 20, the second solder fillet 31 formed on a portion of the second cut-out portion 21 which is an outer side of the insulating container 20, a third solder fillet 30 formed on a portion of the third cut-out portion 22 which is an outer side of the insulating container 20, and a fourth solder fillet 32 formed on a portion of a fourth cut-out portion 23 which is an outer side of the insulating container 20.

In the same manner as the first embodiment, the first solder fillets 34 are solder having a trailing skirt shape in a curved line shape, from the side surface of the second end 35a of the land 35, towards the surface of the mounting electrode 5 exposed to the center portion side of the bottom surface 3 of the insulating container 20 in a plan view.

The second solder fillet 31, the third solder fillet 30, and the fourth solder fillet 32 are solder having a trailing skirt shape in a curved line shape, from the second terminals 26, 24, and 25 which are provided on the first cut-out portion 23, the second cut-out portion 21, and the third cut-out portion 22 provided on the corner portion 7 of the insulating container 20, towards the surface of the land 35 exposed to the outside of the insulating container 20 in a plan view. In the land 35 of the second embodiment, since the sixth ends 35c and 35d are disposed on the outer side with respect to the fifth ends 5c and 5d of the pair of mounting electrodes 5 in a plan view, the third solder fillet 30 is also formed on the third cut-out portion 22 side, and the second solder fillet 31, the third solder fillet 30, and the fourth solder fillet 32 are formed on both sides including the corner portion 7 of the insulating container 20.

According to the second embodiment, it is possible to suppress cracks on the solder fillets which occur due to concentration of the stress caused by the thermal strain, in the same manner as the first embodiment. In addition, since the fourth solder fillet 32, the second solder fillet 31, and the third solder fillet 30 are formed on the first cut-out portion 23, the second cut-out portion 21, and the third cut-out portion 22 on both sides including the corner portion 7 of the insulating container 20, the outside surface of the insulating container 20 is soldered with a sufficient solder amount. Accordingly, in addition to the prevention of the solder cracks performed by the suppression of the thermal strain stress which is an effect of the first embodiment, it is possible to further realize improvement of strength of the soldering and the improvement of reliability.

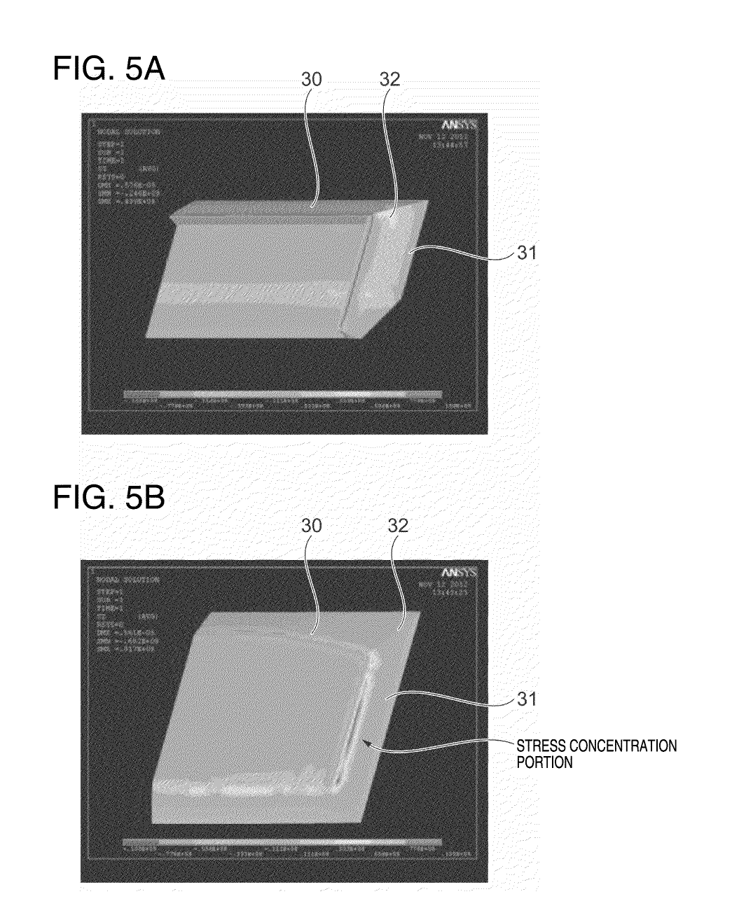

Simulation results of the generation states of the thermal strain stress of the solder fillet are shown in FIGS. 5A and 5B. FIG. 5A shows a generation state of thermal strain stress in the configuration of the first embodiment and the second embodiment according to the invention, and FIG. 5B shows a generation state of thermal strain stress of the configuration of the related art.

In the configuration of the related art shown in FIG. 5B, stress concentration portions shown with a black color in the drawing can be confirmed on the upper portions (portions close to the mounting electrode) of the second solder fillet 31, the third solder fillet 30, and the fourth solder fillet 32. Meanwhile, in the embodiment of the invention shown in FIG. 5A, it is found that the stress concentration portions shown with the black color are not generated on the second solder fillet 31, the third solder fillet 30, and the fourth solder fillet 32. By using the positional configuration of the mounting electrodes 5 of the insulating container 20 according to the invention and the lands 35 of the printed circuit board 38, even in a case where the thermal load is applied to the second solder fillet 31, the third solder fillet 30, and the fourth solder fillet 32, it is possible to reduce concentration of the stress caused by the thermal strain. In addition, the first solder fillet 34 also has the same effect.

In the embodiments described above, the example of the quartz crystal resonator using the quartz crystal for a piezoelectric material as one example of the resonator has been described. However, it is not limited thereto. A resonator which is obtained by loading the vibrating element using lithium tantalate (LiTaO₃), lithium tetraborate (Li₂B₄O₇), lithium niobate (LiNbO₃), lead zirconate titanate (PZT), zinc oxide (ZnO), aluminum nitride (AlN), or the like, or a semiconductor material such as silicon, as another piezoelectric material may be used as the resonator.

In the first embodiment and the second embodiment, the example using the quartz crystal resonator 1 has been described. However, it is not limited to the quartz crystal resonator 1, and the invention can be applied to other quartz crystal resonators, as long as it has the same configuration. Hereinafter, the aspects thereof will be described.

### Oscillator

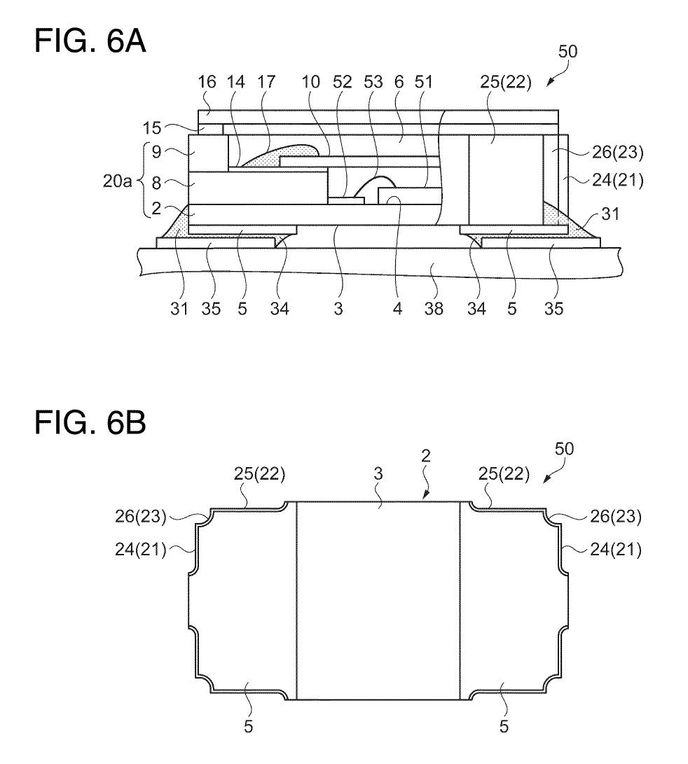

Next, a surface-mounted oscillator using the base substrate according to the invention will be described. FIGS. 6A and 6B show a schematic configuration of a surface-mounted oscillator according to one embodiment of the invention and a mounting structure of the oscillator and a printed circuit board, wherein FIG. 6A is a partial longitudinal front cross-sectional view and FIG. 6B is a bottom view. In this description, the configuration same as the embodiment of the surface-mounted quartz crystal resonator described above will be omitted by denoting the same reference numerals.

An oscillator 50 shown in FIGS. 6A and 6B has a configuration of accommodating the quartz crystal vibrating element 10, and a circuit element (for example, semiconductor element) 51 at least having a function of driving the quartz crystal vibrating element 10 in the loading portion 6 which is a recess of an insulating container (package) 20a as a base substrate obtained by laminating the bottom plate 2, the loading plate 8, and the wall plate 9 which are formed of a sheet-like insulating material such as a ceramics sheet, and sealing the loading portion 6 with the cover 16. The oscillator 50 in this example is a quartz crystal oscillator using the quartz crystal vibrating element 10 using an AT-cut quartz crystal substrate, as one example.

The configuration of the insulating container 20a is almost the same as that in the embodiment of the surface-mounted quartz crystal resonator 1 described above. However, it is different from that in the embodiment in that the insulating container includes a loading portion of the circuit element 51. The embodiment will be described with a focus on the different part.

The insulating container 20a is a circuit wiring board having an approximately rectangular container shape in a plan view, and the mounting electrodes (first terminals) 5 which are provided to contain two corners of the bottom surface (other surface) 3 of the rectangular bottom plate 2 are provided. In the insulating container 20a, the loading portion 6 which is a recess surrounded by an opening portion of the loading plate 8 and the wall plate 9 is provided on the other surface 4 side which has a front and rear relationship with the bottom surface 3 of the bottom plate 2. The circuit element 51 is fixed to the other surface 4 with an adhesive (not shown) or the like, and is electrically connected to a wiring terminal 52 provided on the other surface 4 by a wire-bonding wire 53. The wiring terminal 52 is electrically connected to an inner pad 14 which will be described later, or to the mounting electrodes (first terminals) 5. However, the electrical connection is omitted in the drawing. The other surface 4 is a surface on a side of the insulating container 20a which is connected to the cover 16, and indicates one surface of the bottom plate 2 in the drawing for convenience. Two inner pads 14 which are electrically connected to the quartz crystal vibrating element 10 are provided on an exposed surface of the loading plate 8 which is exposed in the loading portion 6. In the same manner as described above, the first cut-out portion 23, the second cut-out portion 21, and the third cut-out portion 22 are provided on the insulating container 20a, and the second terminals 26, 24, and 25 which are metallic layers are provided on the surfaces thereof.

The circuit element 51 includes a driving circuit or the like as an excitation unit for driving and vibration of the quartz crystal vibrating element 10. More specifically, the driving circuit included in the circuit element 51 drives the quartz crystal vibrating element 10, and supplies a received driving signal to an external portion by amplifying or the like.

The loading portion 6 in which the quartz crystal vibrating element 10 and the circuit element 51 are accommodated, is sealed by seam welding of the cover 16 and the insulating container 20a (wall plate 9) through the seal ring 15 which is provided on the upper surface of the wall plate 9 configuring the insulating container 20a. The cover 16 is also called a lid, and can be formed by, for example, using metal such as alloy 42 (alloy containing 42% of nickel in iron) or kovar (alloy of iron, nickel, and cobalt), ceramics, or glass. In a case where the cover 16 is formed by metal, for example, the seal ring 15 is formed by die cutting of the kovar alloy or the like in a rectangular ring shape. Since the loading portion 6 which is a recessed space formed by the insulating container 20a and the cover 16 is a space for operating the quartz crystal vibrating element 10, it is preferable to be hermetically sealed and enclosed to be a reduced-pressure space or to have the inert gas atmosphere.

The oscillator 50 of the above configuration is mounted by soldering on a circuit board or another printed circuit board as a substrate, or the like. In the drawing, a state is shown in which the oscillator 50 is loaded on the printed circuit board 38 as a substrate in which lands 35 as electrodes are provided, and the lands 35 of the printed circuit board 38 and the mounting electrodes 5 of the oscillator 50 are connected and fixed to each other by soldering. Since the positional relationship between the lands 35 of the printed circuit board 38 and the mounting electrodes 5 of the oscillator 50, and formation of the solder fillets are the same as in the quartz crystal resonator 1 described in the first embodiment described above, the description thereof will be omitted by denoting the same reference numerals.

According to the oscillator 50 described above and the mounting structure using the oscillator 50, in the same manner as the quartz crystal resonator 1 described above, when the thermal load is applied to the mounting electrodes 5 of the soldered insulating container 20a, and the lands 35 as the electrodes of the printed circuit board 38, the first solder fillets 34 of the insulating container 20a on the center portion side of the bottom surface 3 are easily deformed. That is, with the deformation of the first solder fillets 34, the thermal strain stress generated by applying the thermal load is released, and it is possible to prevent the concentration of the thermal strain stress. Accordingly, it is possible to reduce occurrence of the cracks on the second solder fillets and the first solder fillets 34 which occur due to concentration of the stress caused by the thermal strain. Therefore, even when the oscillator 50 using the insulating container 20a as the base substrate according to the invention, and the mounting structure using the oscillator 50 are loaded on a device used in an environment of a high temperature or a low temperature, it is possible to suppress occurrence of malfunction due to solder degradation.

In the description above, the quartz crystal oscillator using the quartz crystal vibrating element 10 using the AT-cut quartz crystal substrate as one example of the vibrating element has been described as an example. However, the vibrating element is not limited thereto. For example, a tuning fork quartz crystal resonator, a surface acoustic wave element, a Micro Electro Mechanical Systems (MEMS), or the like may be used. In addition, a configuration obtained by applying a vibrating element using the other piezoelectric material described in the resonator may be used.

### Sensor Device

The insulating container 20 using the base substrate according to the invention can be applied to a sensor device obtained by loading a sensor element such as a gyro sensor element, an acceleration sensor element, or a pressure sensor element, instead of the quartz crystal vibrating element 10 as the vibrating element described above.

According to such a sensor device, and a mounting structure using the sensor device, in the same manner as the oscillator 50 described above, it is possible to suppress and prevent malfunction such as occurrence of solder cracks due to the thermal load in the state of being surface-mounted on the circuit board or another printed circuit board.

### Electronic Device

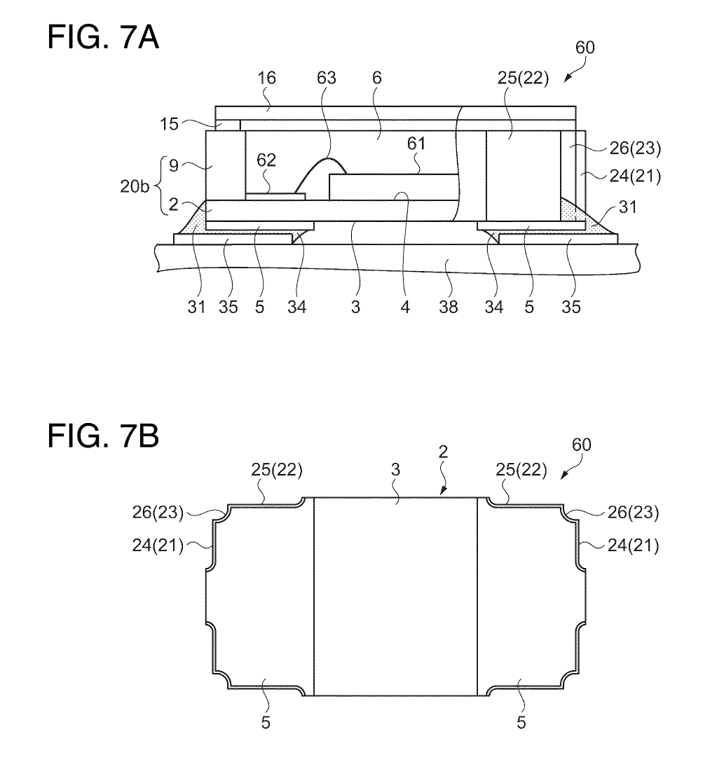

Next, a surface-mounted electronic device using the base substrate according to the invention will be described. FIGS. 7A and 7B show a schematic configuration of the surface-mounted electronic device according to one embodiment of the invention and a mounting structure using the electronic device, wherein FIG. 7A is a partial longitudinal front cross-sectional view and FIG. 7B is a bottom view. In this description, the same configuration as the embodiment of the surface-mounted quartz crystal resonator described above will be omitted by denoting the same reference numerals.

An electronic device 60 shown in FIGS. 7A and 7B has a configuration of accommodating a circuit element (for example, semiconductor element) 61 in the loading portion 6 which is a recess of an insulating container (package) 20b as a base substrate obtained by laminating the bottom plate 2 and the wall plate 9 which are formed of a sheet-like insulating material such as a ceramics sheet, and sealing the loading portion 6 with the cover 16.

The configuration of the insulating container 20b is almost the same as the embodiment of the surface-mounted quartz crystal resonator 1 described above, except for not including the loading plate 8. However, it is different from the embodiment in that the insulating container includes a loading portion of a circuit element 61, instead of the loading portion of the quartz crystal resonator 1. The embodiment will be described with a focus on the different part.

The insulating container 20b is a circuit wiring board having an approximately rectangular container shape in a plan view, and the mounting electrodes (first terminals) 5 which are provided to contain two corners of the bottom surface (other surface) 3 of the substantially rectangular bottom plate 2 are provided. In the insulating container 20b, the loading portion 6 which is a recess surrounded by an opening portion of the wall plate 9 is provided on the other surface 4 side which has a front and rear relationship with the bottom surface 3 of the bottom plate 2. The circuit element 61 is fixed to the other surface 4 with an adhesive (not shown) or the like, and is electrically connected to a wiring terminal 62 provided on the other surface 4 by a wire-bonding wire 63. The wiring terminal 62 is electrically connected to the mounting electrodes (first terminals) 5. However, it is omitted in the drawing. The other surface 4 is a surface on a side of the insulating container 20b which is connected to the cover 16, and indicates one surface of the bottom plate 2 in the drawing for convenience. In the same manner as described above, the first cut-out portion 23, the second cut-out portion 21, and the third cut-out portion 22 are provided on the insulating container 20b, and the second terminals 26, 24, and 25 which are metallic layers are provided on the surfaces thereof.

The circuit element 61 includes, for example, a driving circuit as an excitation unit for driving and vibration of the piezoelectric vibrating element or an electronic circuit for controlling another electronic apparatus.

The loading portion 6 in which the circuit element 61 is accommodated, is sealed by seam welding of the cover 16 and the insulating container 20b (wall plate 9) through the seal ring 15 which is provided on the upper surface of the wall plate 9 configuring the insulating container 20b. The cover 16 is also called a lid, and is formed, for example, by die cutting of the kovar alloy or the like in a rectangular ring shape. The loading portion 6 which is a recessed space formed by the insulating container 20b and the cover 16 is preferably hermetically sealed and enclosed to be a reduced-pressure space or to have the inert gas atmosphere for preventing degradation of the circuit element 61.

The electronic device 60 of the above configuration is mounted by soldering on a circuit board or another printed circuit board as a substrate, or the like. In the drawing, a state is shown in which the electronic device 60 is loaded on the printed circuit board 38 as a substrate in which lands 35 as electrodes are provided, and the lands 35 of the printed circuit board 38 and the mounting electrodes 5 of the electronic device 60 are connected and fixed to each other by soldering. Since the positional relationship between the lands 35 of the printed circuit board 38 and the mounting electrodes 5 of the electronic device 60, and formation of the solder fillets are the same as the quartz crystal resonator 1 described in the first embodiment described above, the description thereof will be omitted by denoting the same reference numerals.

According to the electronic device 60 described above and the mounting structure using the electronic device 60, in the same manner as the quartz crystal resonator 1 described above, when the thermal load is applied to the mounting electrodes 5 of the soldered insulating container 20b and the lands 35 as the electrodes of the printed circuit board 38, the first solder fillets 34 of the insulating container 20b on the center portion side of the bottom surface 3 are easily deformed. That is, with the deformation of the first solder fillets 34, the thermal strain stress generated by applying the thermal load is released, and it is possible to prevent the concentration of the thermal strain stress. Accordingly, it is possible to reduce occurrence of the cracks on the second solder fillets 31 and the first solder fillets 34 which occur due to concentration of the stress caused by the thermal strain. Therefore, even when the electronic device 60 using the insulating container 20b as the base substrate according to the invention is loaded on a device used in an environment of a high temperature or a low temperature, it is possible to suppress occurrence of malfunction due to solder degradation.

In the description of the electronic device described above, the electronic device 60 of the configuration using the circuit element 61 has been described as an example. However, the invention is not limited thereto, and for example, the invention can be applied to a configuration of connecting various electronic components to a circuit pattern formed on the other surface 4, or to a configuration of loading another electronic element.

In the descriptions of the quartz crystal resonator 1, the oscillator 50, the sensor device, and the electronic device 60 described above, the configuration of providing the mounting electrodes 5 as the pair of mounting terminals on the bottom surface 3 of the insulating container 20 and providing the pair of lands 35 on the printed circuit board 38 to oppose the mounting electrodes 5, has been described. However, the invention is not limited thereto. The mounting electrodes 5 and the lands 35 may have a configuration of being provided with one for each to oppose each other, or may have a configuration of having three or more thereof provided so as to oppose each other. Also, in such a configuration, the configuration of the solder fillets is the same, and accordingly the same effects as described above can be obtained.

In the quartz crystal resonator 1, the oscillator 50, the sensor device, and the electronic device 60 described above, the example of loading and forming elements such as the quartz crystal vibrating element 10, the circuit elements 51 and 61 or wiring on the loading portion 6 provided on the other surface 4 side has been described. However, it is not limited thereto. In the quartz crystal resonator 1, the oscillator 50, the sensor device, and the electronic device 60 according to the invention, a configuration of providing the loading portion on one surface (bottom surface 3) side may be used, or a configuration of loading and forming elements such as the quartz crystal vibrating element 10, the circuit elements 51 and 61 or wiring on the loading portion of the one surface (bottom surface 3) side may be used, and the same effects can be obtained.

### Electronic Apparatus

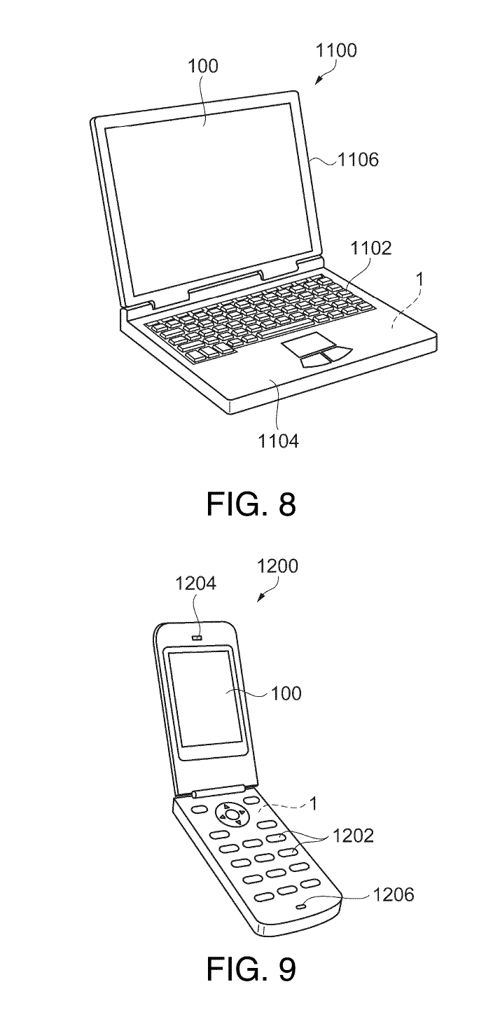

An electronic apparatus obtained by applying the configuration of the mounting structure obtained by soldering the surface-mounted quartz crystal resonator 1, the oscillator 50, the electronic device 60, the sensor device, or the like as the surface-mounted device using the base substrate according to one embodiment of the invention to the printed circuit board 58, will be described in detail, with reference to FIGS. 8 to 10. In the description, the examples to which the quartz crystal resonator 1 is applied will be shown.

FIG. 8 is a schematic perspective view showing a configuration of a mobile type (or notebook type) personal computer as an electronic apparatus including the quartz crystal resonator 1 and the printed circuit board 38 according to one embodiment of the invention. In this drawing, a personal computer 1100 is configured with a main body portion 1104 including a keyboard 1102 and a display unit 1106 including a display portion 100, and the display unit 1106 is rotatably supported through a hinge structure with respect to the main body portion 1104. The quartz crystal resonator 1 is mounted in such a personal computer 1100 as a reference signal source or the like.

FIG. 9 is a schematic perspective view showing a configuration of a mobile phone (including PHS) as an electronic apparatus including the quartz crystal resonator 1 and the printed circuit board 38 according to one embodiment of the invention. In the drawing, a mobile phone 1200 includes a plurality of manipulation buttons 1202, an ear piece 1204, and a mouth piece 1206, and the display portion 100 is disposed between the manipulation buttons 1202 and the ear piece 1204. The quartz crystal resonator 1 is mounted in such a mobile phone 1200, as a reference signal source or the like.

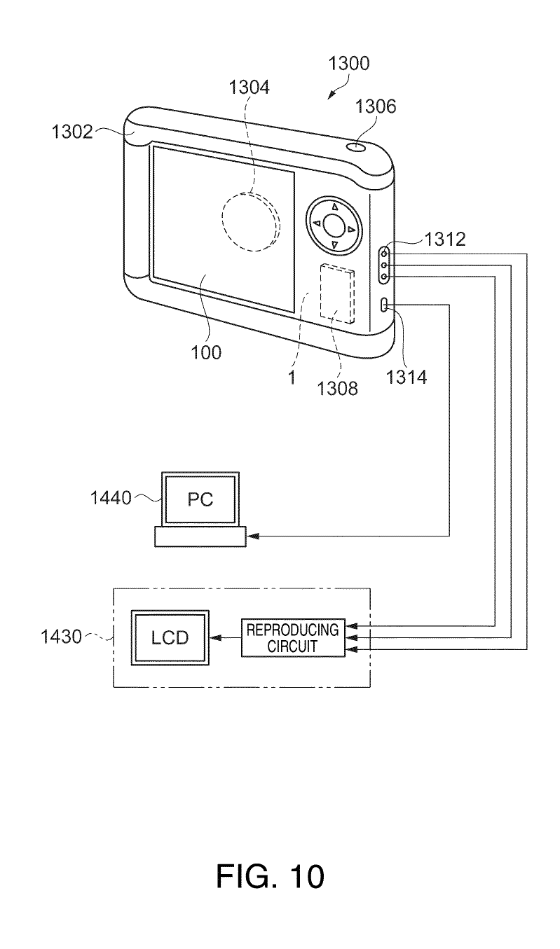

FIG. 10 is a schematic perspective view showing a configuration of a digital still camera as an electronic apparatus including the quartz crystal resonator 1 and the printed circuit board 38 according to one embodiment of the invention. In this drawing, connection with an external device is also simply shown. Herein, while a typical camera exposes a silver halide photography film to light by a light image of a subject, a digital still camera 1300 performs photoelectric conversion of the light image of the subject by an imaging element such as a charged coupled device (CCD) and generates an imaging signal (image signal). The display portion 100 is provided on a rear surface of a case (body) 1302 of the digital still camera 1300 and has a configuration of performing display based on the imaging signal generated by the CCD, and the display portion 100 functions as a finder which displays the subject as an electronic image. In addition, a light receiving unit (module) 1304 including an optical lens (imaging optical system), CCD, or the like is provided on a front surface side (rear surface side in the drawing) of the case 1302.

If a photographer confirms a subject image displayed on the display portion 100 and presses a shutter button 1306, an imaging signal of CCD at this time point is transferred and stored in a memory 1308. In the digital still camera 1300, a video signal output terminal 1312 and an input and output terminal for data communication 1314 are provided on a side surface of the case 1302. As shown in the drawing, the video signal output terminal 1312 is connected to a television monitor 1430, and the input and output terminal for data communication 1314 is connected to a personal computer 1440, if necessary. With predetermined manipulation, the imaging signal stored in the memory 1308 is output to the television monitor 1430 or the personal computer 1440. The quartz crystal resonator 1 is mounted in such a digital still camera 1300, as a reference signal source or the like.

In addition to the personal computer (mobile type personal computer) in FIG. 8, the mobile phone in FIG. 9, and the digital still camera in FIG. 10, the quartz crystal resonator 1 according to one embodiment of the invention, for example, can be applied to an electronic apparatus such as an ink jet type discharging apparatus (for example, ink jet printer), a laptop type personal computer, a television, a video camera, a video tape recorder, a car navigation apparatus, a pager, an electronic organizer (including communication function), an electronic dictionary, a calculator, an electronic game machine, a word processor, a workstation, a videophone, a security television monitor, electronic binoculars, a POS terminal, a medical apparatus (for example, an electronic thermometer, a blood pressure meter, a blood glucose meter, an electrocardiogram measuring device, an ultrasonic diagnostic apparatus, and an electronic endoscope), a fish finder, various measurement apparatuses, meters (for example, meters of a vehicle, an aircraft, and a ship), a flight simulator, or the like.

### Moving Object

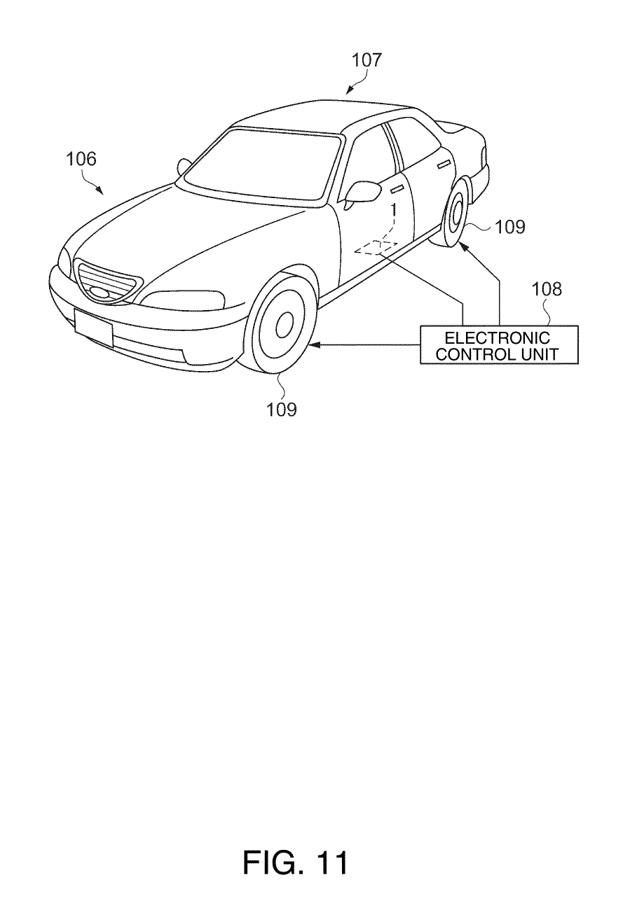

FIG. 11 is a perspective view schematically showing a vehicle as one example of a moving object. The mounting structure using the quartz crystal resonator 1 and the printed circuit board 38 according to the invention is mounted in a vehicle 106. For example, as shown in the drawing, the quartz crystal resonator 1 is mounted in the vehicle 106 as a moving object, and an electronic control unit (module) 108 for controlling tires 109 and the like is loaded on a car body 107. In addition to this, the quartz crystal resonator 1 can be widely applied to electronic control units (ECU) of keyless entry, an immobilizer, car navigation systems, car air conditioners, an anti-lock brake system (ABS), airbags, a tire pressure monitoring system (TPMS), engine control, a battery monitor of a hybrid car or an electric car, a car body attitude control system, and the like. Particularly, the configuration of the quartz crystal resonator 1 and the printed circuit board 38 according to the invention is suitable for the vehicle 106 which has a wide operating temperature range and is used in a severe temperature environment, since it can improve reliability with respect to the temperature load of soldering.

The entire disclosure of Japanese Patent Application No. 2012-265018, filed Dec. 4, 2012 is expressly incorporated by reference herein.

What is claimed is:

1. A base substrate comprising:
mounting terminals which are connected to electrode pads provided on a mounting substrate using a joining material,
wherein each of the mounting terminals includes:
a first end which is disposed in outside of a region of the electrode pad, in a plan view; and
a second end which is overlapped with the inside of the region of the electrode pad.

2. A mounting structure comprising:
a first substrate on which mounting terminals are provided; and
a second substrate on which external terminals to which the mounting terminals are attached using a joining material are provided,
wherein a first end of each of the mounting terminals is disposed in outside of a region of the external terminal, in a plan view,
a second end of each of the mounting terminals is overlapped with the inside of the region of the external terminal, in a plan view,
a first fillet is provided from the first end to each of the external terminals, and
a second fillet is provided from the second end to each of the external terminals.

3. The mounting structure according to claim 2,
wherein the first substrate includes a pair of the mounting terminals,
the second substrate includes a pair of the electrode pads,
the end on a side where the pair of the mounting terminals oppose each other is set to be the first end,
the end on a side opposite to the side where the pair of the mounting terminals oppose each other is set to be the second end,
the first fillet is provided from the first end to each of the electrode pads, and
the second fillet is provided from the second end to each of the electrode pads.

4. The mounting structure according to claim 3,
wherein the first substrate includes an end portion which extends in a direction intersecting with the first end of each of the mounting terminals,
the end portion is overlapped with the inside of each of the electrode pads, in a plan view, and
a third fillet is provided from the end portion to each of the electrode pads.

5. A module comprising the mounting structure according to claim 2.

6. A module comprising the mounting structure according to claim 3.

7. A module comprising the mounting structure according to claim 4.

8. An electronic apparatus comprising the mounting structure according to claim 2.

9. An electronic apparatus comprising the mounting structure according to claim 3.

10. An electronic apparatus comprising the mounting structure according to claim 4.

11. A moving object comprising the mounting structure according to claim 2.

12. A moving object comprising the mounting structure according to claim 3.

13. A moving object comprising the mounting structure according to claim 4.
